(19) United States
(12) Patent Application Publication
(10) Pub. No.: US 2011/0007469 A1
(43) Pub. Date: Jan. 13, 2011

(54) SLIDER ACTUATOR

(75) Inventor: Pasi Kemppinen, Tampere (FI)

Correspondence Address: Nokia, Inc., 6021 Connection Drive, MS 2-5-520, Irving, TX, 75039, US

(73) Assignee: NOKIA CORPORATION, Espoo (FI)

(21) Appl. No.: 12/919,753

(22) PCT Filed: Feb. 26, 2008
(86) PCT No.: PCT/FI08/50089

§ 371 Date: Aug. 26, 2010

(51) Int. Cl. G06F 1/16; F16C 29/02; H05K 7/00

(52) U.S. Cl. 361/679.08; 384/26; 361/679.01; 361/679.02; 361/679.21

(57) ABSTRACT

The invention relates to a slider actuator (203) suitable for controlling relative movement between sliding elements (201, 202). The slider actuator includes two or more contact parts (209, 210) capable of forming mechanical contacts with one of the sliding elements in at least two locations of that sliding element (201). Each of the at least two contact parts is capable of supporting the sliding element in mutually opposite directions. The fact that the slider actuator includes two or more contact parts that are capable of supporting a sliding element in mutually opposite directions in different locations of the sliding element makes possible, for example, to extend the maximum range of movement of the sliding elements and/or to in crease a number of stable mutual positions of the sliding elements.

### RELATED APPLICATION

This application was originally filed as PCT Application No. PCT/FI2008/050089 filed Feb. 26, 2008.

### FIELD OF THE INVENTION

The invention relates to a slider actuator suitable for controlling relative movement between sliding elements. Furthermore, the invention relates to slider module, to a device comprising sliding elements, and to a method for controlling relative movement between sliding elements.

### BACKGROUND

A device, e.g. a mobile phone, may comprise sliding elements that are mechanically connected to each other with a sliding mechanism. For example, a communication device can comprise a cover element that is connected with a slider mechanism to a main body of the communication device. The slider mechanism may comprise a slider actuator that is arranged to control relative movement between the sliding elements. For example, the slider actuator can be arranged to prevent the sliding elements from changing their mutual position due the changes of the posture in which a user holds the device. Operation of the slider actuator can be based on one or more springs that are arranged to produce force that prevents unstable and undesired relative movement between the sliding elements.

FIGS. 1a, 1b, 1c, 1d, and 1e illustrate a device that comprises a first sliding element 101 and a second sliding element 102. The first sliding element 101 is capable of being slid in mutually opposite sliding directions D+ and D− with respect to the second sliding element 102. FIG. 1a shows a side-view of the device, FIG. 1b shows a section view A-A of the device, and FIGS. 1c-1e show a section view B-B of the device. The device comprises a slider actuator 103 that has a first end 104 and a second end 105. In the first end 104 of the slider actuator there is a hole the walls of which represent a contact part capable of supporting the first sliding element 101 in both of the mutually opposite sliding directions D+ and D−. Correspondingly, in the second end 105 of the slider actuator there is a hole the walls of which represent a contact part capable of supporting the second sliding element 102 in both of the mutually opposite sliding directions D+ and D−. The first end 104 of the slider actuator is connected to the sliding element 101 with a pivot pin 106. The second end 105 of the slider actuator is connected to the sliding element 102 with a pivot pin 107. The pivot pin 106 is fixed to the sliding element 101 and the pivot pin 107 is fixed to the sliding element 102. When the sliding elements 101 and 102 are slid with respect to each other springs 108 of the slider actuator are being stretched or compressed. FIG. 1d illustrates a situation in which the sliding element 101 has been slid from the position shown in FIG. 1c towards the sliding direction D− with respect to the sliding element 102. FIG. 1e illustrates a situation in which the sliding element 101 has been further slid towards the sliding direction D− with respect to the sliding element 102. In a certain mutual position of the sliding elements 101 and 102, the springs 108 can operate either as pressure springs that tend to lengthen themselves and thus to shorten the slider actuator 103, or as extension springs that tend to shorten themselves and thus to lengthen the slider actuator, or the springs can be at their neutral positions. If the springs 108 are pressure springs that tend to shorten the slider actuator, the slider actuator tends to move the sliding elements 101 and 102 from the side positions shown in FIGS. 1c and 1e to the center position shown in FIG. 1d. If the springs are extension springs that tend to lengthen the slider actuator, the center position shown in FIG. 1d is labile and the slider actuator tends to move the sliding elements 101 and 102 from the center position to one or other of the side positions shown in FIGS. 1c and 1e. A maximum range of movement of the sliding element 101 with respect to the sliding element 102, i.e. a distance between extreme mutual positions of the sliding elements, depends at least partly on how much the springs 108 can be stretched and/or compressed.

### SUMMARY

In accordance with a first aspect of the invention a new slider actuator is provided. The slider actuator comprises:
a first end capable of being connected to a first sliding element, and
a second end capable of being connected to a second sliding element, the first sliding element and the second sliding element being arranged to allow relative movement between the first sliding element and the second sliding element,
wherein the first end includes at least two contact parts configured to couple with the first sliding element in at least two locations of the first sliding element, each of the at least two contact parts being capable of supporting the first sliding element in mutually opposite directions.

In accordance with a second aspect of the invention a new a slider module is provided. The slider module comprises:
a first sliding element,
a second sliding element, the first sliding element and the second sliding element being arranged to allow relative movement between the first sliding element and the second sliding element, and
a slider actuator having a first end connected to the first sliding element and a second end connected to the second sliding element,
wherein the first end of the slider actuator includes at least two contact parts configured to couple with the first sliding element in at least two locations of the first sliding element, each of the at least two contact parts being capable of supporting the first sliding element in mutually opposite directions.

In accordance with a third aspect of the invention a new device is provided. The device comprises:
a first sliding element,
a second sliding element, the first sliding element and the second sliding element being arranged to allow relative movement between the first sliding element and the second sliding element, and
a slider actuator having a first end connected to the first sliding element and a second end connected to the second sliding element,
wherein the first end of the slider actuator includes at least two contact parts configured to couple with the first sliding element in at least two locations of the first sliding element, each of the at least two contact parts being capable of supporting the first sliding element in mutually opposite directions.

In a device according to one exemplifying embodiment of the invention, the second end of the slider actuator includes at least two other contact parts configured to couple with the second sliding element in at least two locations of the second sliding element, each of the at least two other contact parts being capable of supporting the second sliding element in mutually opposite directions.

In a device according to one exemplifying embodiment of the invention, the first sliding element is a cover element that is arranged to cover, in a situation in which the device is in a closed position, at least part of at least one of the following: a keyboard and a display screen.

The device may be one of the following: a mobile phone, a handheld computer, a portable computer.

In accordance with a fourth aspect of the invention a new method is provided. The method comprises:
sliding a first sliding element and a second sliding element with respect to each other, and
using a slider actuator for controlling relative movement between the first sliding element and the second sliding element,
wherein the slider actuator includes a first end connected to the first sliding element and a second end connected to the second sliding element and the first end of the slider actuator includes at least two contact parts configured to couple with the first sliding element in at least two locations of the first sliding element, each of the at least two contact parts being capable of supporting the first sliding element in mutually opposite directions.

In a method according to one exemplifying embodiment of the invention, the second end of the slider actuator includes at least two other contact parts configured to couple with the second sliding element in at least two locations of the second sliding element, each of the at least two other contact parts being capable of supporting the second sliding element in mutually opposite directions.

In a method according to one exemplifying embodiment of the invention, the at least two contact parts are pins arranged to protrude from the surface of the first end of the slider actuator, each pin being capable of directing supporting force to a wall of a pin-specific guide track located on the first sliding element.

In a method according to one exemplifying embodiment of the invention, one of the at least two contact parts is a gear tooth on the surface of the first end and another of the at least two contact parts is a pin arranged to protrude from the surface of the first end, the gear tooth being capable of directing supporting force to a slot located on the first sliding element and the pin being capable of directing supporting force to a wall of a guide track located on the first sliding element.

In a method according to one exemplifying embodiment of the invention, the at least two contact parts are gear teeth on the surface of the first end of the slider actuator, each gear tooth being capable of directing supporting force to a toothed bar of the first sliding element. The first end of the slider actuator may comprise a steering part arranged to protrude from the surface of the first end of the slider actuator, the steering part being movable in a guide track located on the first sliding element. The toothed bar may have a concave shape facing towards the gear teeth of the first end of the slider actuator.

A number of embodiments of the invention are described in accompanied dependent claims.

Various exemplifying embodiments of the invention both as to constructions and to methods of operation, together with additional objects and advantages thereof, will be best understood from the following description of specific embodiments when read in connection with the accompanying drawings.

The embodiments of the invention presented in this document are not to be interpreted to pose limitations to the applicability of the appended claims. The verb “to comprise” is used in this document as an open limitation that does not exclude the existence of also unrecited features. The features recited in depending claims are mutually freely combinable unless otherwise explicitly stated.

### BRIEF DESCRIPTION OF THE FIGURES

The exemplifying embodiments of invention and their advantages are explained in greater detail below with reference to the accompanying drawings, in which

FIGS. 1a, 1b, 1c, 1d and 1e illustrate a device that comprises sliding elements and a slider actuator according to the prior art,

FIG. 2a shows a slider actuator according to an embodiment of the invention and FIGS. 2b, 2c, 2d and 2e show a slider module comprising the slider actuator shown in FIG. 2a,

FIG. 3a shows a slider actuator according to an embodiment of the invention and FIGS. 3b, 3c, 3d, 3e and 3f show a slider module comprising the slider actuator shown in FIG. 3a,

FIG. 4a shows a slider actuator according to an embodiment of the invention and FIGS. 4b, 4c, 4d, and 4e show a slider module comprising the slider actuator shown in FIG. 4a,

FIGS. 5a and 5b show a slider module according to an embodiment of the invention,

FIGS. 5c and 5d show a slider module according to an embodiment of the invention,

FIG. 6 shows a device according to an embodiment of the invention, and

FIG. 7 is a flow chart of a method according to an embodiment of the invention for controlling movement of a first sliding element with respect to a second sliding element.

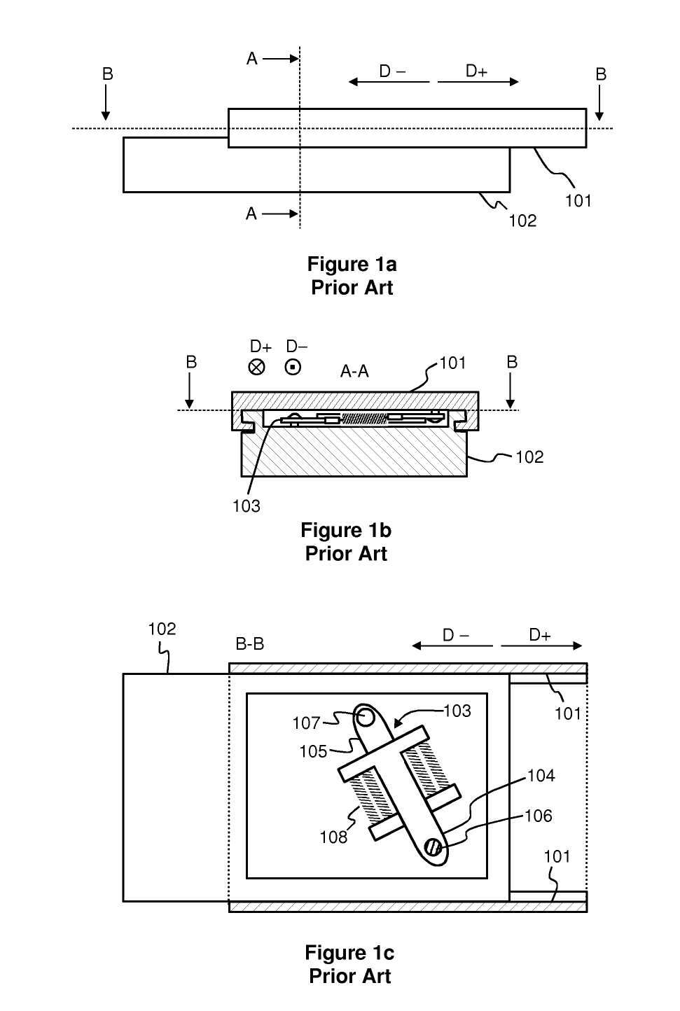

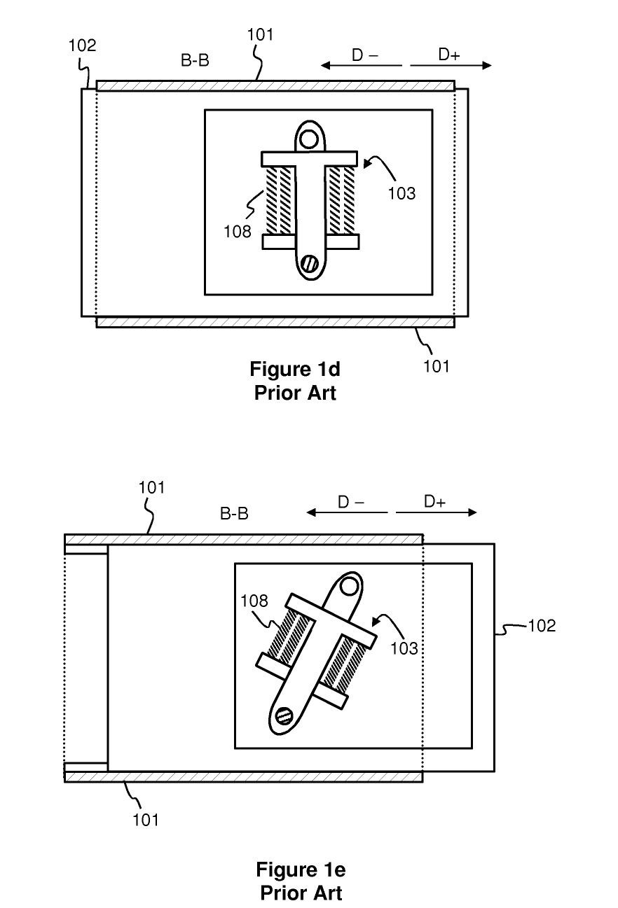

FIGS. 1a, 1b, 1c, 1d and 1e have been explained earlier in this document in connection with the background of the invention.

### DETAILED DESCRIPTION

A slider actuator according to an embodiment of the invention comprises:

a first end capable of being connected to a first sliding element, and

a second end capable of being connected to a second sliding element, the first sliding element and the second sliding element having means for allowing relative movement between the first sliding element and the second sliding element,

wherein the first end includes means for coupling with the first sliding element in at least two locations of the first sliding element, each of the mechanical contacts being capable of supporting the first sliding element in mutually opposite directions.

In a slider actuator according to an embodiment of the invention, the second end includes means for coupling with the second sliding element in at least two locations of the second sliding element, each of the mechanical contacts being capable of supporting the second sliding element in mutually opposite directions.

In a slider actuator according to an embodiment of the invention, the means for coupling with the first sliding element are pins arranged to protrude from the surface of the first end, each pin being capable of directing supporting force to a wall of a guide track located on the first sliding element.

In a slider actuator according to an embodiment of the invention, the means for coupling with the first sliding element are gear teeth on the surface of the first end, each gear tooth being capable of directing supporting force to a toothed bar of the first sliding element. The first end of the slider actuator may further comprise additional steering means for keeping the gear teeth in contact with the toothed bar.

In a slider actuator according to an embodiment of the invention, the means for coupling with the first sliding element comprise a gear tooth on the surface of the first end and a pin arranged to protrude from the surface of the first end, the gear tooth being capable of directing supporting force to a slot located on the first sliding element and the pin being capable of directing supporting force to a wall of a guide track located on the first sliding element.

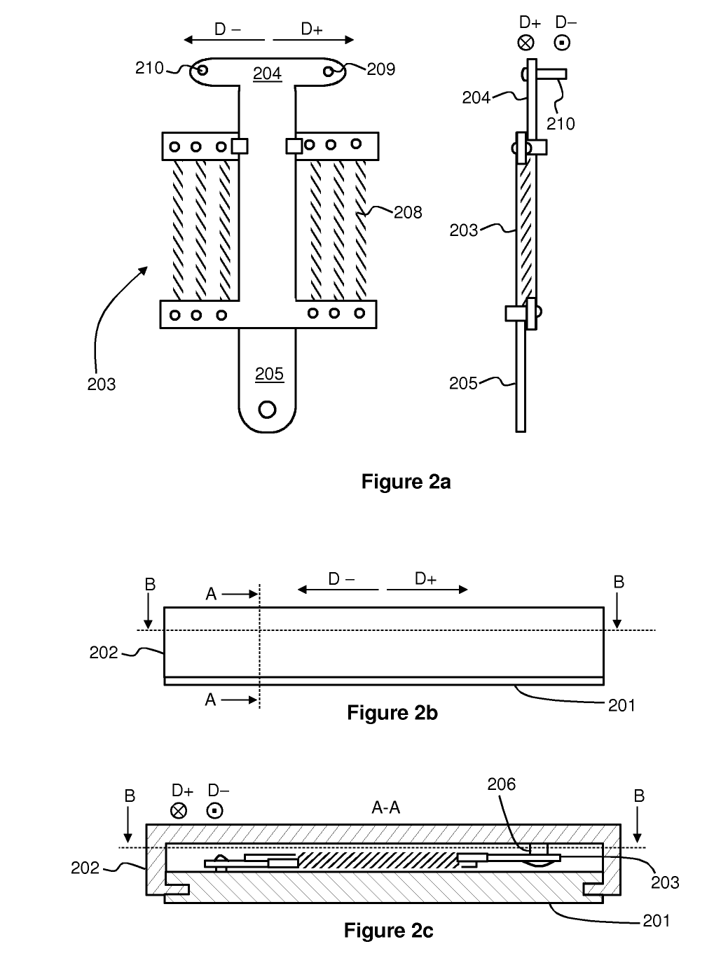

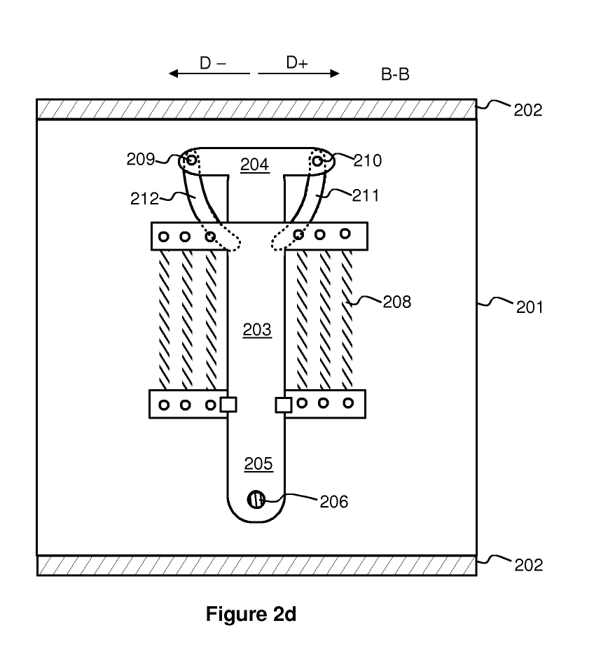

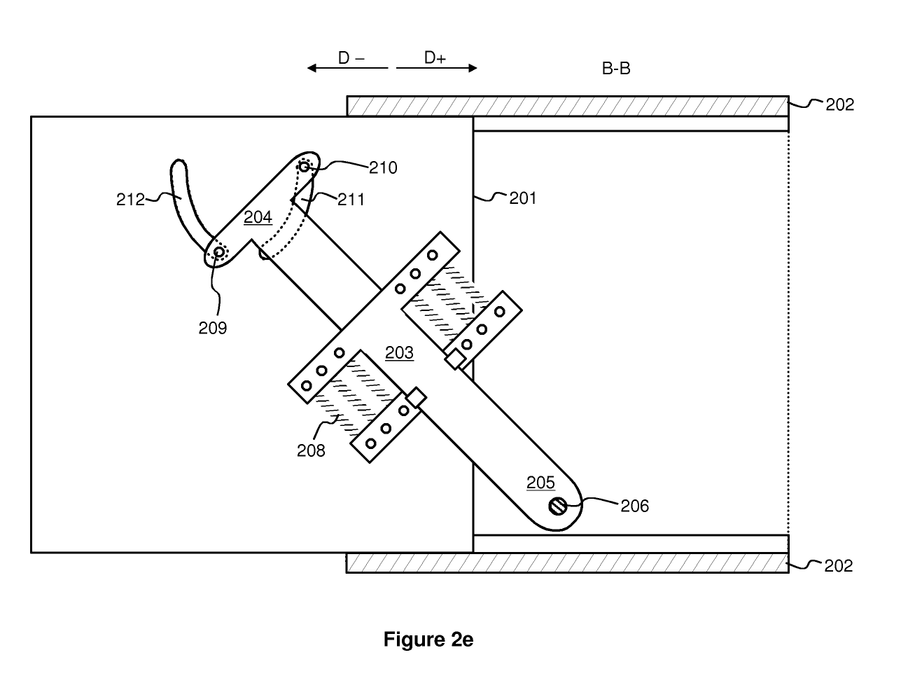

FIG. 2a shows a slider actuator 203 according to an embodiment of the invention seen from two different viewing directions. The slider actuator comprises a first end 204 that is capable of being connected to a first sliding element, and a second end 205 that is capable of being connected to a second sliding element. The first end 204 includes two contact parts 209 and 210 that are located successively in mutually opposite sliding directions D− and D+. Each of the contact parts 209 and 210 is a pin capable of supporting the first sliding element in both of the mutually opposite sliding directions. In the second end 205 of the slider actuator there is a hole with the aid of which the second end can be connected to the second sliding element.

FIGS. 2b, 2c, 2d and 2e show a slider module comprising the slider actuator 203 shown in FIG. 2a. The slider module comprises a first sliding element 201 and a second sliding element 202. The first sliding element 201 is capable of being slid in mutually opposite sliding directions D+ and D− with respect to the second sliding element 202. FIG. 2b shows a side-view of the slider module, FIG. 2c shows a section view A-A of the device, and FIGS. 2d-2e show a section view B-B of the device. As shown in FIGS. 2d and 2e the pin 209 of the slider actuator can move in a pin-specific arched guide track 212 located on the first sliding element 201. The guide track 212 can be an arched elongated hole or an arched groove located on the first sliding element 201. Correspondingly, the pin 210 of the slider actuator can move in a pin-specific arched guide track 211 located on the first sliding element 201. The guide track 211 can be an arched elongated hole or an arched groove located on the first sliding element 201. Each of the pins 209 and 210 is capable of directing supporting force to a wall of the corresponding pin-specific arched guide track in both of the mutually opposite sliding directions D− and D+. The second end of the slider actuator is connected to the second sliding element 202 with a pivot pin 206. FIGS. 2d and 2e show a cross section of the pivot pin 206 as can be understood with the aid of FIG. 2c.

FIG. 2d shows a situation in which the slider module is in its center position and FIG. 2e shows a situation in which the slider module is in one of its two side positions, i.e. the sliding element 201 has been slid to its extreme position in the direction D− with respect to the sliding element 202. In the center position of the slider module (FIG. 2d), pins 209 and 210 are being pressed against ends of the arched guide tracks 212 and 211, respectively, if springs 208 tend to shorten themselves and thus to lengthen the slider actuator when the slider module is in the center position. Therefore, unlike the device shown in FIGS. 1a-1e, the slider module shown in FIGS. 2b-2e has a stable center position. When the sliding element 201 is slid towards the direction D− or D+, the pin 209 or 201 is moving towards another end of the corresponding arched guide track 212 or 211. The stability of the center position can be increased by increasing the physical distance between the pins 209 and 210.

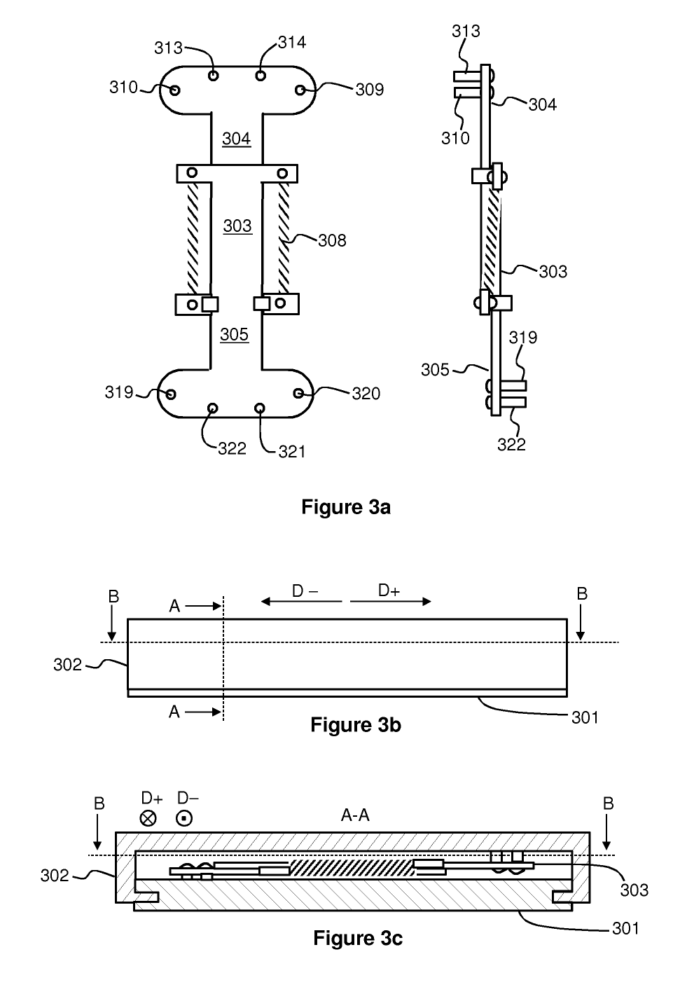

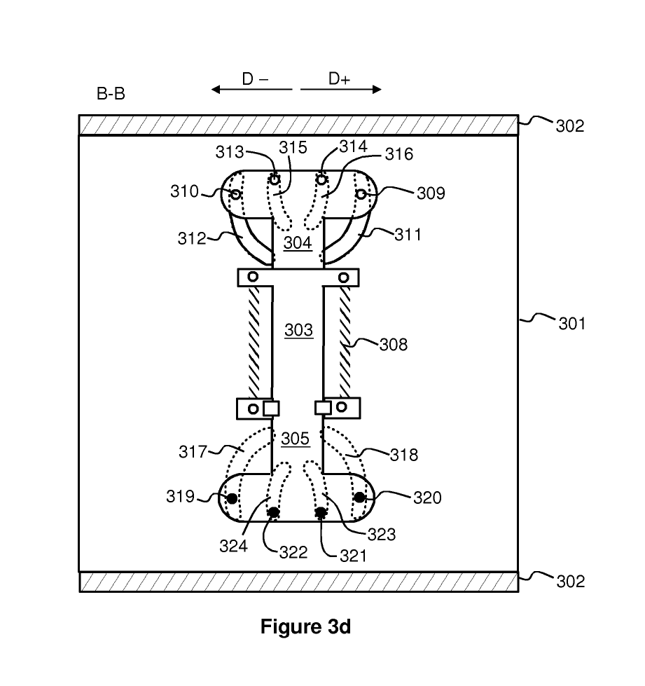

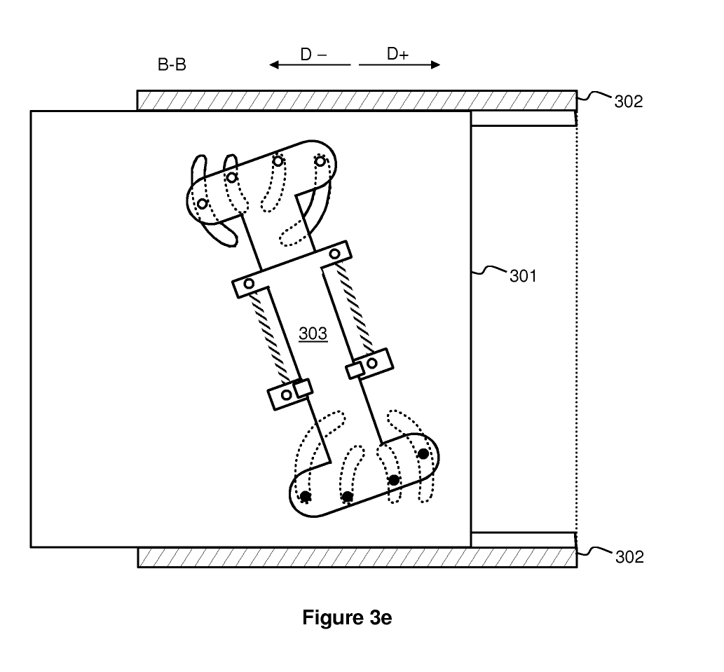

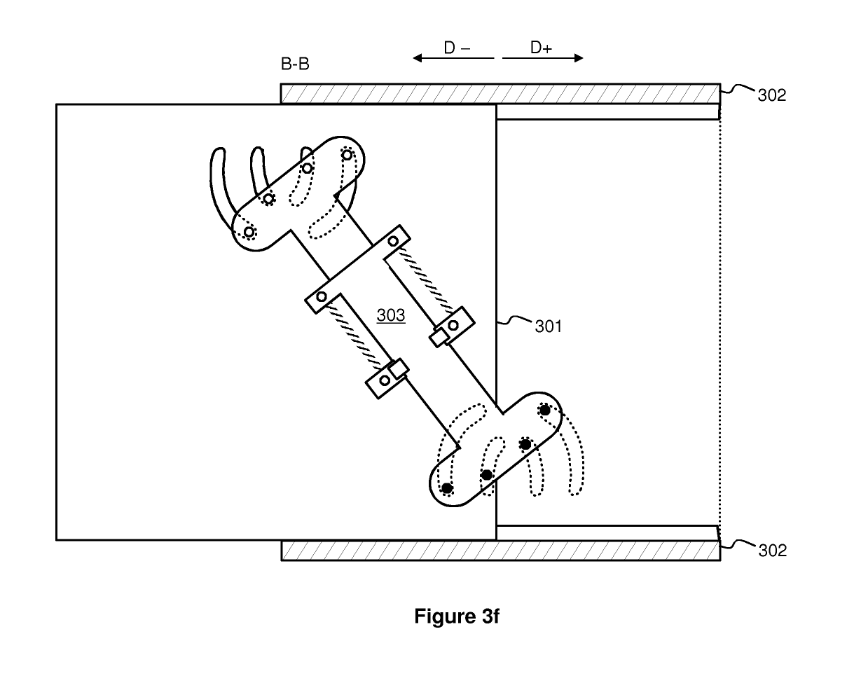

FIG. 3a shows a slider actuator 303 according to an embodiment of the invention seen from two different viewing directions. The slider actuator comprises a first end 304 that is capable of being connected to a first sliding element, and a second end 305 that is capable of being connected to a second sliding element. The first end 304 includes four contact parts 309, 310, 313 and 314 that are located substantially successively in mutually opposite sliding directions D− and D+. Each of the contact parts 309, 310, 313 and 314 is a pin capable of supporting the first sliding element in both of the mutually opposite sliding directions. The second end 305 of the slider actuator includes four contact parts 319, 320, 321 and 322 that are located substantially successively in the mutually opposite sliding directions D and D+. Each of the contact parts 319, 320, 321 and 322 is a pin capable of supporting the second sliding element in both of the mutually opposite sliding directions.

FIGS. 3b, 3c, 3d, 3e and 3f show a slider module comprising the slider actuator 303 shown in FIG. 3a. The slider module comprises a first sliding element 301 and a second sliding element 302. The first sliding element 301 is capable of being slid in mutually opposite sliding directions D+ and D− with respect to the second sliding element 302. FIG. 3b shows a side-view of the slider module, FIG. 3c shows a section view A-A of the device, and FIGS. 3d-3f show a section view B-B of the device. As shown in FIGS. 3d, 3e and 3f, the pins 309, 310, 313 and 314 of the slider actuator can move in pin-specific arched guide tracks 311, 312, 315, and 316 of the first sliding element 301, respectively. The guide tracks 311, 312, 315, and 316 can be arched elongated holes or arched grooves located on the first sliding element 301. Correspondingly, the pins 319, 320, 321 and 322 of the slider actuator can move in pin-specific arched guide tracks 317, 318, 323, and 324 of the second sliding element 302, respectively. The guide tracks 317, 318, 323, and 324 can be arched elongated holes or arched grooves located on the second sliding element 302. Each of the pins 309, 310, 313 and 314 is capable of directing supporting force to a wall of the corresponding pin-specific arched guide track in both of the mutually opposite sliding directions D− and D+, and each of the pins 319, 320, 321 and 322 is capable of directing supporting force to a wall of the corresponding pin-specific arched guide track in both of the mutually opposite sliding directions D− and D+. FIGS. 3d, 3e and 3f show a cross section of the pins 319, 320, 321 and 322 as can be understood with the aid of FIG. 3c.

FIG. 3d shows a situation in which the slider module is in its center position. FIG. 3f shows a situation in which the slider module is in one of its two extreme side positions, i.e. the sliding element 301 has been slid to its extreme position in the direction D− with respect to the sliding element 302. FIG. 3e shows a situation in which the slider module in a position between the center position shown in FIG. 3d and the extreme side position shown in FIG. 3f. The center position is stable in the same way as in conjunction with the slider module shown in FIGS. 2b-2e. The position shown in FIG. 3e is also stable, because at both ends of the slider actuator two pins are being pressed against ends of arched guide tracks if springs 308 tend to shorten themselves and thus to lengthen the slider actuator when the slider module is in that position.

As illustrated with FIGS. 2b-2e and 3b-3f, the fact that the slider actuator includes two or more contact parts (pins) that are located substantially successively in mutually opposite sliding directions and that are capable of supporting a sliding element in both of the mutually opposite sliding directions makes possible to increase the number of stable mutual positions of sliding elements.

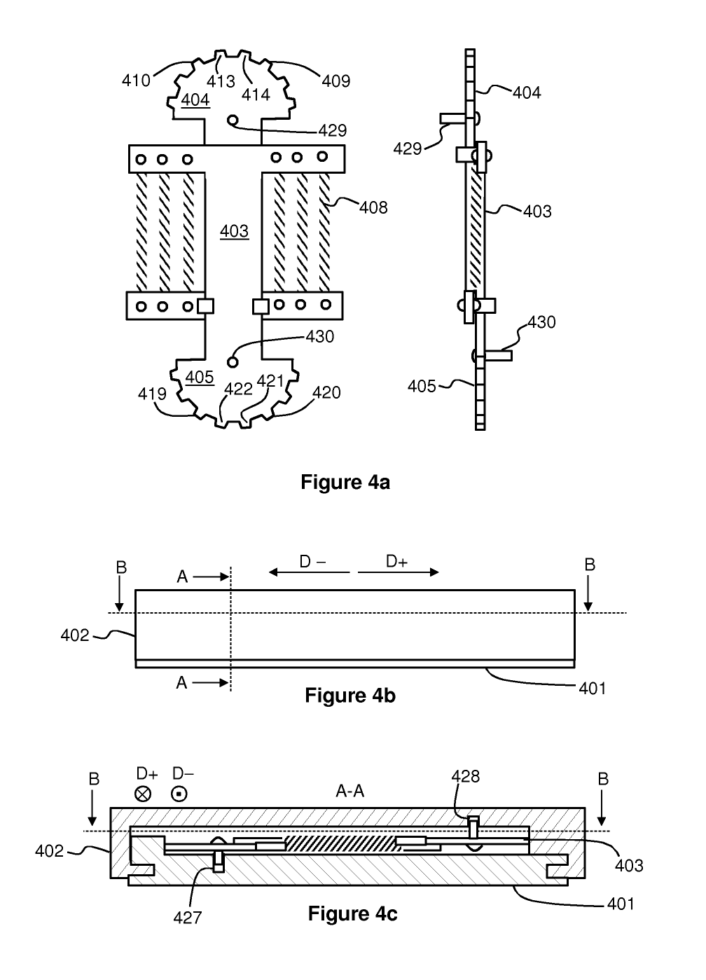

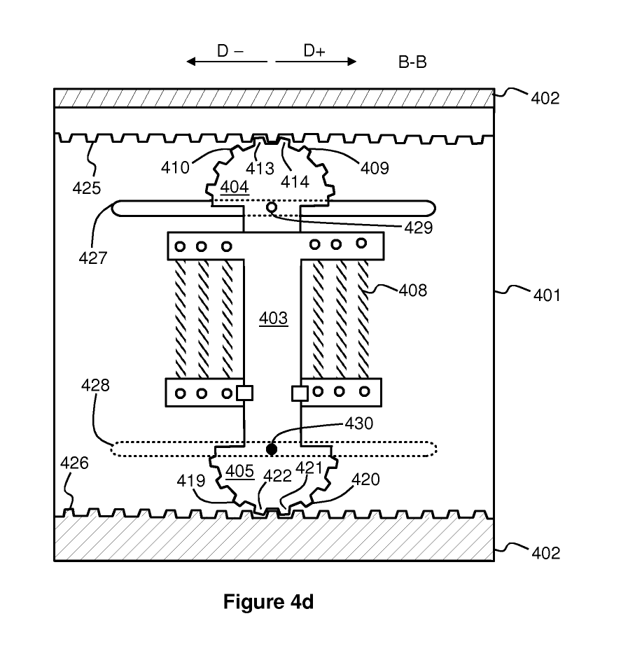

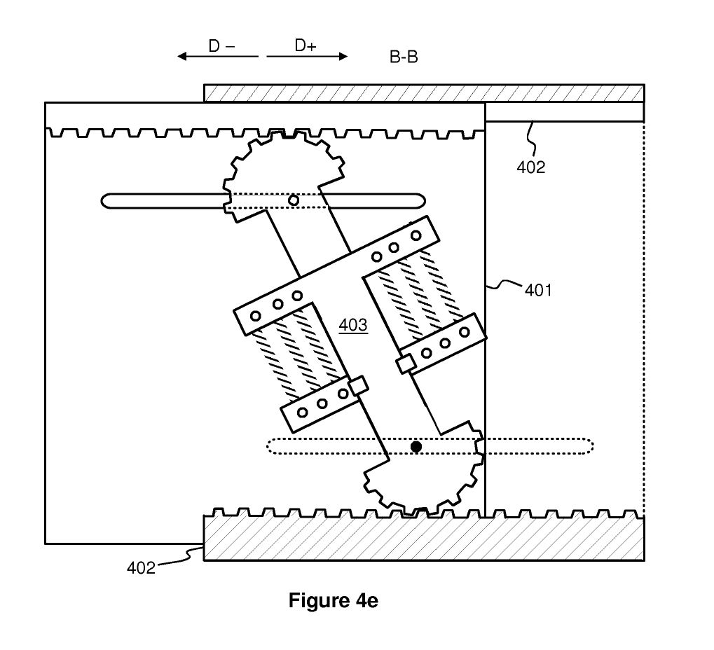

FIG. 4a shows a slider actuator 403 according to an embodiment of the invention seen from two different viewing directions. The slider actuator comprises a first end 404 that is capable of being connected to a first sliding element, and a second end 405 that is capable of being connected to a second sliding element. The first end 404 includes contact parts, e.g. 409, 410, 413, and 414, that are located substantially successively in mutually opposite sliding directions D− and D+. The contact parts are gear teeth on a bowed surface of the first end. The gear teeth are capable of supporting the first sliding element in both of the mutually opposite sliding directions. The second end 405 of the slider actuator includes contact parts, e.g. 419, 420, 421 and 342, that are located substantially successively in the mutually opposite sliding directions D− and D+. The contact parts of the second end are gear teeth capable of supporting the second sliding element in both of the mutually opposite sliding directions.

FIGS. 4b, 4c, 4d, and 4e show a slider module comprising the slider actuator 403 shown in FIG. 4a. The slider module comprises a first sliding element 401 and a second sliding element 402. The first sliding element 401 is capable of being slid in mutually opposite sliding directions D+ and D− with respect to the second sliding element 402. FIG. 4b shows a side-view of the slider module, FIG. 4c shows a section view A-A of the device, and FIGS. 4d-4e show a section view B-B of the device. As can be seen from FIGS. 4d and 4e, the gear teeth of the first end 404 of the slider actuator are capable of directing supporting force to a toothed bar 425 of the first sliding element in both of the mutually opposite sliding directions D+ and D−, and the gear teeth of the second end 405 of the slider actuator are capable of directing supporting force to a toothed bar 426 of the second sliding element in both of the mutually opposite sliding directions D+ and D−. FIG. 4d shows a situation in which the slider module is in its center position. FIG. 4e shows a situation in which the sliding element 401 has been slid towards the direction D− with respect to the sliding element 402.

In a slider module according to an embodiment of the invention, the first end 404 of the slider actuator 403 comprises a steering part 429 arranged to protrude from the surface of the first end. The steering part is movable, in the mutually opposite sliding directions+ and D−, in a guide track 427 of the first sliding element 401. The guide track 427 can be an elongated hole or a groove located on the first sliding element 401. The second end 405 of the slider actuator 403 comprises a steering part 430 arranged to protrude from the surface of the second end. The steering part is movable, in the mutually opposite sliding directions+ and D−, in a guide track 428 of the second sliding element 402. The guide track 428 can be an elongated hole or a groove located on the second sliding element 402. The steering part 429 and the guide track 427 are arranged to prevent the gear teeth of first end 404 from jumping off the toothed bar 425 when the slider module is, for example, dropped. Correspondingly, the steering part 430 and the guide track 428 are arranged to prevent the gear teeth of second end 405 from jumping off the toothed bar 426 when the slider module is, for example, dropped.

As can be seen from FIGS. 4d and 4e, the fact that the slider actuator includes a plurality of contact parts (gear teeth) that are located substantially successively in mutually opposite sliding directions and that are capable of supporting a sliding element in both of the mutually opposite sliding directions makes possible to extend the maximum range of movement of the sliding elements without a need to increase a stretching/compression range of springs 408.

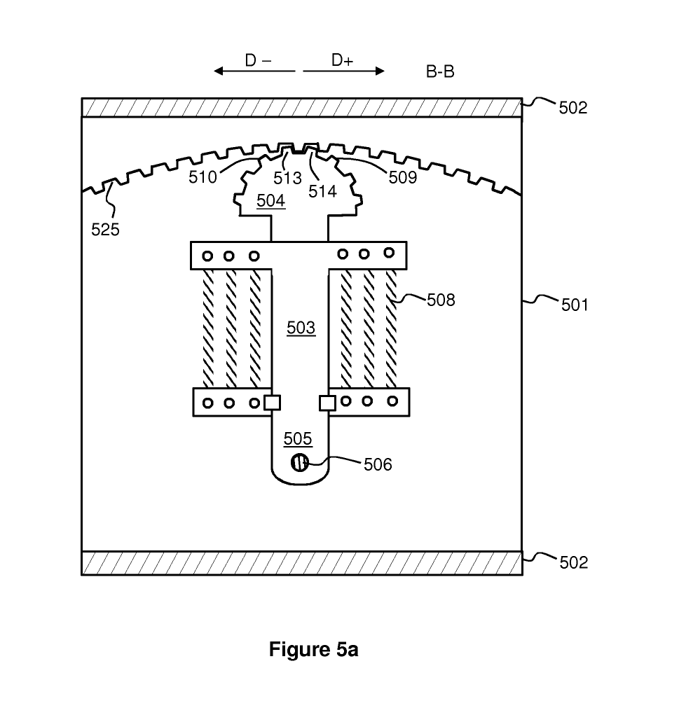

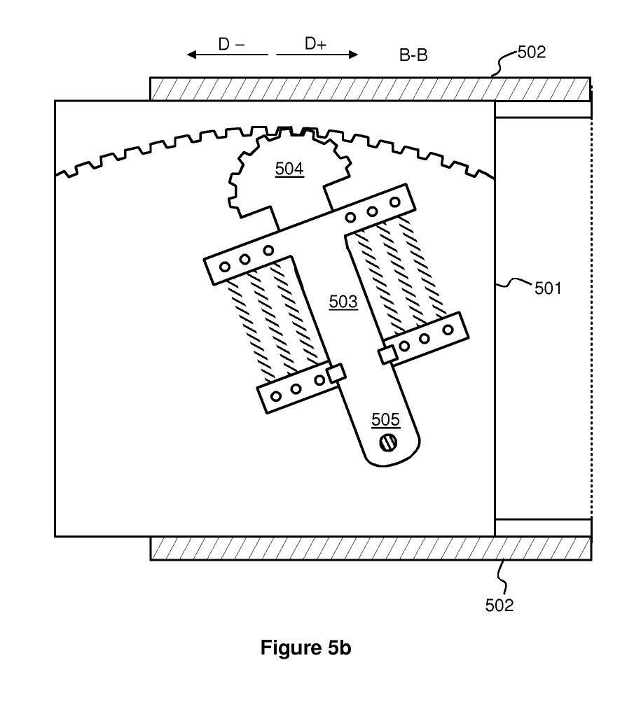

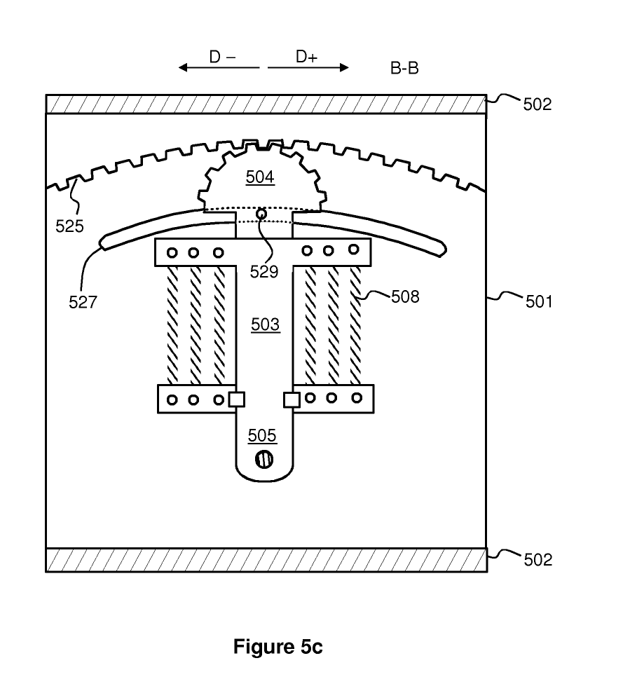

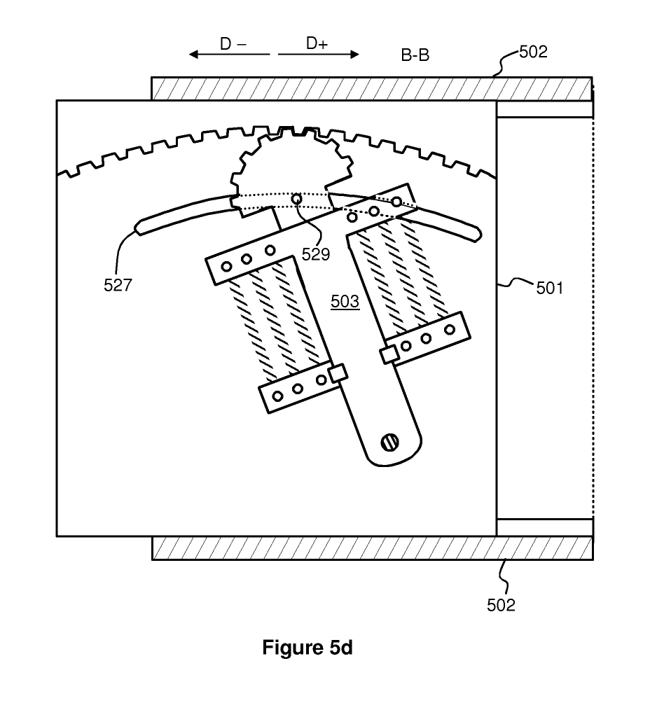

FIGS. 5a and 5b show a slider module comprising a slider actuator 503 according to an embodiment of the invention. The slider module comprises a first sliding element 501 and a second sliding element 502. The first sliding element 501 is capable of being slid in mutually opposite sliding directions D+ and D− with respect to the second sliding element 502. The slider actuator comprises a first end 504 that is connected to the first sliding element 501, and a second end 505 that is connected to the second sliding element 502. The first end 504 includes contact parts, e.g. 509, 510, 513, and 514, that are located substantially successively in the mutually opposite sliding directions D and D+. The contact parts of the first end are gear teeth capable of supporting the first sliding element 501 in both of the mutually opposite sliding directions. The second end 505 of the slider actuator is connected to the second sliding element 502 with a pivot pin 506.

The gear teeth of the first end 504 of the slider actuator are capable of directing supporting force to a toothed bar 525 of the first sliding element 501 in both of the mutually opposite sliding directions D+ and D−. The toothed bar 525 has a concave shape facing towards the gear teeth of the first end of the slider actuator. FIG. 5a shows a situation in which the slider module is in its center position. FIG. 5b shows a situation in which the sliding element 501 has been slid towards the direction D− with respect to the sliding element 502. The concave shape of the toothed bar 525 increases the maximum range of movement of the sliding elements 501 and 502, which can be achieved with a certain stretching/compression range of springs 508.

FIGS. 5c and 5d show a slider module comprising a slider actuator 503 according to an embodiment of the invention. The slider module is otherwise similar to the slider module shown in FIGS. 5a and 5b but the first end 504 of the slider actuator 503 comprises a steering part 529 arranged to protrude from the surface of the first end and the first sliding element 501 comprises an arched guide track 527 that can be e.g. an arched elongated hole or an arched groove. The steering part 529 is movable in the guide track 527. The steering part 529 and the guide track 527 are arranged to keep the gear teeth of first end 504 in contact with the toothed bar 525.

In a slider module according to an embodiment of the invention, there is only one gear tooth on the surface of the first end 504 of the slider actuator 503. The said gear tooth constitutes one contact part capable of forming a mechanical contact with the first sliding element 501 in a first location of the first sliding element and capable of supporting the first sliding element in mutually opposite directions. The steering part 529 that can be e.g. a pin constitutes another contact part capable of forming a mechanical contact with the first sliding element 501 in a second location of the first sliding element and capable of supporting the first sliding element in mutually opposite directions.

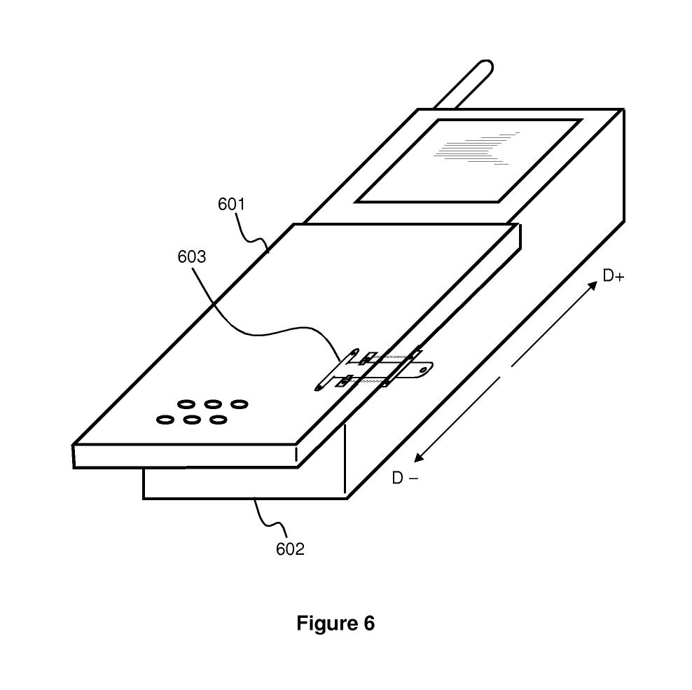

FIG. 6 shows a device according to an embodiment of the invention. The device can be, for example, a mobile phone, a handheld computer, and/or a portable computer. The device comprises:

a first sliding element 601,

a second sliding element 602, the first sliding element being capable of being slid in mutually opposite sliding directions D−, D+ with respect to the second sliding element, and

a slider actuator 603 (inside the device) having a first end connected to the first sliding element and a second end connected to the second sliding element,

wherein the first end of the slider actuator includes at least two contact parts located successively in the mutually opposite sliding directions D−, D+, each of the at least two contact parts being capable of supporting the first sliding element in both of the mutually opposite sliding directions D−, D+.

In a device according to an embodiment on the invention the second end of the slider actuator includes at least two other contact parts located successively in the mutually opposite sliding directions, each of the at least two other contact parts being capable of supporting the second sliding element in both of the mutually opposite sliding directions.

In a device according to an embodiment on the invention the first sliding element is a cover element that is arranged to cover, in a situation in which the device is in a closed position, at least part of at least one of the following: a keyboard and a display screen.

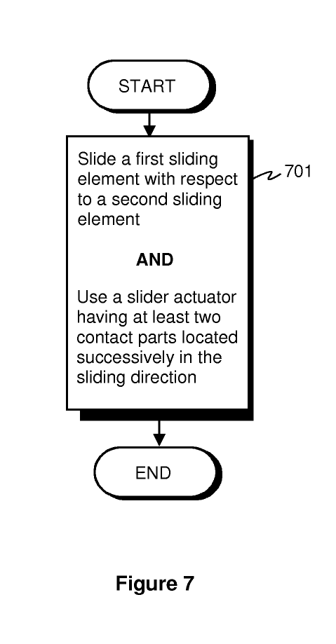

FIG. 7 is a flow chart of a method according to an embodiment of the invention for controlling movement of a first sliding element with respect to a second sliding element. The method comprises:

sliding, in phase 701, a first sliding element with respect to a second sliding element towards one of mutually opposite sliding directions, and

using, in the phase 701, a slider actuator for controlling movement of the first sliding element with respect to the second sliding element,

wherein the slider actuator being used includes a first end connected to the first sliding element and a second end connected to the second sliding element and the first end of the slider actuator includes at least two contact parts located successively in the mutually opposite sliding directions, each of the at least two contact parts being capable of supporting the first sliding element in both of the mutually opposite sliding directions.

In a method according to an embodiment of the invention, the second end of the slider actuator being used includes at least two other contact parts located successively in the mutually opposite sliding directions, each of the at least two other contact parts being capable of supporting the second sliding element in both of the mutually opposite sliding directions.

In a method according to an embodiment of the invention, the at least two contact parts of the first end of the slider actuator are pins arranged to protrude from the surface of the first end of the slider actuator, each pin being capable of directing supporting force to a wall of a pin-specific guide track located on the first sliding element.

In a method according to an embodiment of the invention, the at least two contact parts of the first end of the slider actuator are gear teeth on a bowed surface of the first end of the slider actuator, each gear tooth being capable of directing supporting force to a toothed bar of the first sliding element, the toothed bar being substantially parallel to the mutually opposite sliding directions.

In a method according to an embodiment of the invention, the first end of the slider actuator comprises a steering part arranged to protrude from the surface of the first end of the slider actuator, the steering part being movable, in the mutually opposite sliding directions, in a guide track located on the first sliding element.

In a method according to an embodiment of the invention, the teeth of the toothed bar are located in a straight line. In a method according to another embodiment of the invention, the toothed bar has a concave shape facing towards the gear teeth of the first end of the slider actuator.

In a method according to an embodiment of the invention, one of the at least two contact parts of the first end of the slider actuator is a gear tooth on the surface of the first end and another of the said at least two contact parts is a pin arranged to protrude from the surface of the first end. The gear tooth is capable of directing supporting force to a slot located on the first sliding element and the pin is capable of directing supporting force to a wall of a guide track located on the first sliding element.

While there have been shown and described and pointed out fundamental novel features of the invention as applied to embodiments thereof, it will be understood that various omissions and substitutions and changes in the form and details of the devices and methods described may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. The specific examples provided in the description given above should not be construed as limiting. Therefore, the invention is not limited merely to the embodiments described above, many variants being possible without departing from the scope of the inventive idea defined in the independent claims.

1-24. (canceled)

25. A slider actuator, comprising:
a first end capable of being connected to a first sliding element; and
a second end capable of being connected to a second sliding element, the first sliding element and the second sliding element being arranged to allow relative movement between the first sliding element and the second sliding element,
wherein the first end includes at least two contact pads configured to couple with the first sliding element in at least two locations of the first sliding element, each of the at least two contact parts being capable of supporting the first sliding element in mutually opposite directions.

26. A slider actuator according to claim 25, wherein the second end includes at least two other contact parts configured to couple with the second sliding element in at least two locations of the second sliding element, each of the at least two other contact parts being capable of supporting the second sliding element in mutually opposite directions.

27. A slider actuator according to claim 25, wherein the at least two contact parts are pins arranged to protrude from the surface of the first end, each pin being capable of directing supporting force to a wall of a guide track located on the first sliding element.

28. A slider actuator according to claim 25, wherein the at least two contact parts are gear teeth on the surface of the first end, each gear tooth being capable of directing supporting force to a toothed bar of the first sliding element.

29. A slider actuator according to claim 28, wherein the first end comprises a steering part arranged to protrude from the surface of the first end, the steering part being movable in a guide track located on the first sliding element.

30. A slider actuator according to claim 25, wherein one of the at least two contact parts is a gear tooth on the surface of the first end and another of the at least two contact parts is a pin arranged to protrude from the surface of the first end, the gear tooth being capable of directing supporting force to a slot located on the first sliding element and the pin being capable of directing supporting force to a wall of a guide track located on the first sliding element.

31. A slider module, comprising:
a first sliding element,
a second sliding element, the first sliding element and the second sliding element being arranged to allow relative movement between the first sliding element and the second sliding element; and
a slider actuator having a first end connected to the first sliding element and a second end connected to the second sliding element,
wherein the first end of the slider actuator includes at least two contact parts configured to couple with the first sliding element in at least two locations of the first sliding element, each of the at least two contact parts being capable of supporting the first sliding element in mutually opposite directions.

32. A slider module according to claim 31, wherein the second end of the slider actuator includes at least two other contact parts configured to couple with the second sliding element in at least two locations of the second sliding element, each of the at least two other contact parts being capable of supporting the second sliding element in mutually opposite directions.

33. A slider module according to claim 31, wherein the at least two contact parts are pins arranged to protrude from the surface of the first end of the slider actuator, each pin being capable of directing supporting force to a wall of a pin-specific guide track located on the first sliding element.

34. A slider module according to claim 31, wherein the at least two contact parts are gear teeth on the surface of the first end of the slider actuator, each gear tooth being capable of directing supporting force to a toothed bar of the first sliding element.

35. A slider module according to claim 34, wherein the first end of the slider actuator comprises a steering part arranged to protrude from the surface of the first end of the slider actuator, the steering part being movable in a guide track located on the first sliding element.

36. A slider module according to claim 34, wherein the toothed bar has a concave shape facing towards the gear teeth of the first end of the slider actuator.

37. A slider module according to claim 31, wherein one of the at least two contact parts is a gear tooth on the surface of the first end and another of the at least two contact parts is a pin arranged to protrude from the surface of the first end, the gear tooth being capable of directing supporting force to a slot located on the first sliding element and the pin being capable of directing supporting force to a wall of a guide track located on the first sliding element.

38. A device, comprising:
a first sliding element,
a second sliding element, the first sliding element and the second sliding element being arranged to allow relative movement between the first sliding element and the second sliding element, and
a slider actuator having a first end connected to the first sliding element and a second end connected to the second sliding element,
wherein the first end of the slider actuator includes at least two contact parts configured to couple with the first sliding element in at least two locations of the first sliding element, each of the at least two contact parts being capable of supporting the first sliding element in mutually opposite directions.

39. A device according to claim 38, wherein the second end of the slider actuator includes at least two other contact parts configured to couple with the second sliding element in at least two locations of the second sliding element, each of the at least two other contact parts being capable of supporting the second sliding element in mutually opposite directions.

40. A device according to claim 38, wherein the device is at least one of the following: a mobile phone, a handheld computer and a portable computer.

41. A device according to claim 38, wherein the first sliding element is a cover element that is arranged to cover, in a situation in which the device is in a closed position, at least part of at least one of the following: a keyboard and a display screen.
